(19) United States
(12) Patent Application Publication
(10) Pub. No.: US 2009/0059975 A1
(43) Pub. Date: Mar. 5, 2009

(54) LASER MODULE FOR PROJECTION DISPLAYS

(75) Inventors: Nathan Brilliant, Denver, CO (US); Dave Fish, Golden, CO (US)

Correspondence Address: PEARNE & GORDON LLP, 1801 EAST 9TH STREET, SUITE 1200, CLEVELAND, OH, 44114-3108, US

(73) Assignee: OC OERLIKON BALZERS AG, Balzers (LI)

(21) Appl. No.: 12/043,340

(22) Filed: Mar. 6, 2008

Related U.S. Application Data
(60) Provisional application No. 60/909,721, filed on Apr. 3, 2007.

(30) Foreign Application Priority Data
Mar. 30, 2007 (DE) 102007015766.7

(51) Int. Cl. H01S 5/026

(52) U.S. Cl. 372/22

(57) ABSTRACT

A laser module with a linear laser diode array includes multiple, mutually separated laser cells. A nonlinear optical material serves to double the frequency of the radiation emitted by the laser cells. The linear laser diode array and the nonlinear optical material are so positioned relative to each other that the resulting frequency-doubled radiation propagates, within the nonlinear optical material and essentially within mutually separated columns associable with the laser cells, both in the direction of the radiation emitted by the laser cells and in the opposite direction. The laser module includes optical elements which divert the bidirectionally propagating frequency-doubled radiation in a manner whereby, upon diversion between the columns in the respective other direction, the radiation propagates in the nonlinear optical material, so that frequency-doubled light ultimately exits the nonlinear optical material in only one direction.

The present invention relates to a laser module with a diode laser array assembled with an optical nonlinear material for 2nd harmonic generation. The present invention relates as well to a method for 2nd harmonic generation.

### BACKGROUND OF THE INVENTION

Laser diodes are nowadays broadly used in applications. Especially advanced is the fabrication of infrared lasers. Here laserdiodes are commercially available with power level of multiple Watts. Meanwhile diode lasers for wavelengths within the visible spectrum are realized. Especially red diode lasers and blue diode lasers are available. However, the intensity of such lasers is still far away from the intensitiy level available with infrared diode lasers. Especially the realization of a high intensity green laser is still difficult. High intensity level of such visible diode lasers is required if they are planned to be used for example in projection systems. For such high intensity applications people are using more and more infrared lasers in combination with a optical nonlinear Material in order to get frequency doubling. Typically within such optical nonlinear material 2nd harmonic generation happens in two directions: The first direction is parallel to the propagation of the infrared light, the second direction is the reverse direction of the first direction. In order to provoke 2nd harmonic generation infrared light is coupled into the optical nonlinear material in high intensity. In order to realize such high intensity the part of the infrared light, which was not uses for the 2nd harmonic generation within its first pass is reflected back into the optical nonlinear material, for example with the help of a mirror. In cases where within the laser module the VECSEL-principle is used this mirror forms part of the laser cavity of the laser diode and the optical nonlinear material is situated within this cavity.

As already mentioned, the light generated though 2nd harmonic generation leaves the optical nonlinear material in two opposite directions. In order to use this light for laser projection applications both beams need to be brought together to form one single beam. One of the critical parameters of within projectors is the size of the beam emitted by the light source. the combination of two counter propagating beams to one single beam, as described above always increases the size of the total beam. This is an important disadvantage.

In the laser module as described above one has to take into account that it is not possible just to directly reflect back one of the generated beams into the optical nonlinear material. The reason one cannot direct the second harmonic directly back with the fundamental is that it requires very precise phase matching. If the second harmonic is in phase with the fundamental, that gives better conversion. If it is out of phase, there is back conversion. If the phase is not controlled, it switches rapidly from in phase to out of phase creating noise.

For many applications the light of one single infrared laser diode is not sufficient. Therefore quite often a high number of laser diodes in a row are combined to an array of laser diodes. Throughout this disclosure a laser diode within a laser diode array will be named lasercell. Lasercells within laser diode arrays are realized with certain spacing to their neighbors, in order that they don't disturb each other. Light from such a laser diode array which is coupled into an optical nonlinear material leads again to 2nd harmonic generation, the generated light propagating in a first direction and counterpropagating in a second direction and finally leaving the optical nonlinear material in to opposed sides. If this generated light is now combined this results in two rows of beamlets. Again there is the disadvantage of increased beam size, especially if the application is within laser projection.

It is therefore one of the objectives of the present invention to disclose a laser module on the basis of 2^{nd} harmonic generation from the light emitted by a laser diode array, the resulting generated field of beamlets having reduced size.

This objective is met with a laser module according to the present invention. In such an inventive laser module the light generated, propagating and leaving the optical nonlinear material in one of the two directions is redirected into the optical nonlinear material in such a way that it propagates between the infrared beams as emitted by the laser diode. Therefore the generated light is finally exiting the optical nonlinear material in the other of the two directions only. The reason why this is possible is connected to the fact that the infrared light as emitted by the laser diode array propagates within the optical nonlinear material within well separated columns. In the case of VECSELs this means that each lasercell constitutes its own cavity, spaced apart from the cavities of the neighboring lasercells. In the spaces between the cavities there is essentially not infrared light. “Essentially not infrared light” in this case means that if there is infrared light it is at very low intensity which is not significant. There is if any at most very low intensity light between the columns which can be denied. Therefore the generated light can propagate between the columns without being disturbed. Generated light, exiting the optical nonlinear material therefore exits it in areas within the columns and areas between the columns. The resulting size of the light field is in this case increased by the size of one beamlet only.

The invention will now be described in more detail with the help of different embodiments and in examples based on the figures.

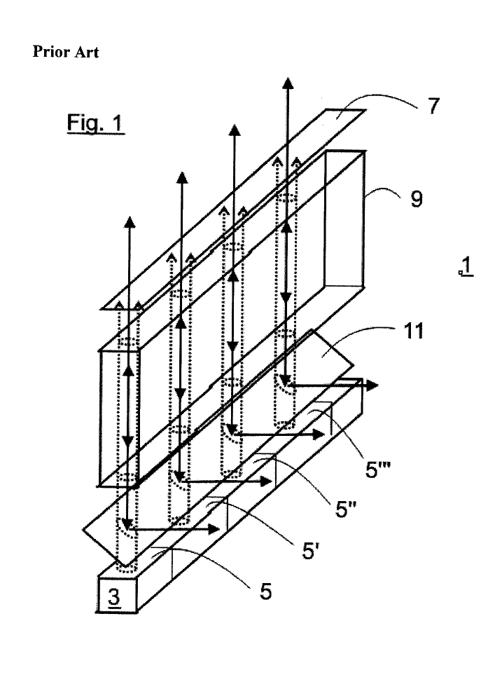

FIG. 1 shows part of a laser module 1 as known in the art. The laser module 1 comprises a laser diode array 3 with lasercells 5, 5′, 5″, 5′″. The lasercells are arranged on a length of 0.98 mm with a spacing of 320 μm. The lasercells emit infrared light with a wavelength of 1120 nm in vapor. This is shown schematically in FIG. 1 with the arrows having broken lines. Laser module 1 in addition comprises a mirror 7 which reflects light with a wavelength of 1120 nm essentially in total and essentially completely transmitts light with a wavelength of 560 nm.

The laser diode array 3 and the mirror 7 together form a number of single VECSELs corresponding to the number of lasercells within the array and well separated from each other. The laser module 1 in addition comprises a PPLN-cuboid 9 of periodically poled Lithium Niobate (PPLN). The PPLN-cuboid 9 is arranged between the laser diode array 3 and therefore within the cavities of the VECSELs. The infrared beams of the VECSELS are well spaced apart from each other. Therefore within the PPLN-cuboid there exist columns with high intensity of infrared light and spacings between these columns with essentially no intensity of infrared light. The PPLN-cuboid 9 has dimensions of 1.5 mm width and 5 mm length. Along this length of 5 mm the infrared light propagating within the cuboid interacts with the PPLN in such a way that frequency doubled light with a wavelength of 560 nm, which is green light, is generated. This generated green light, which propagates in the direction of the infrared light as well as counter propagating is schematically shown in figure one with the arrows with continuous lines. The green light exits the PPLN-cuboid 9 in direction to the mirror 7 and in direction the laser diode array 3. The green light transmitts through the mirror 7 because of the spectral characteristics of the mirror and finally exits the laser module. An additional mirror 11 is arranged in a tilted fashion between the laser diode array 3 and the PPLN-cuboid 9. The mirror 11 essentially completely transmitts the infrared light with wavelength 1120 nm and essentially completely reflects the light with wavelength of 560 nm. By this it is guarantied that the generated green light is reflected away from the laser diode array 3 whereas the VECSEL cavitiy is essentially not disturbed. It is clear that generated green light, transmitting through the mirror 7 propagating in one direction and generated green light, being reflected by mirror 11 propagating in another direction need to be combined for use in the application and therefore lead to an increased beam.

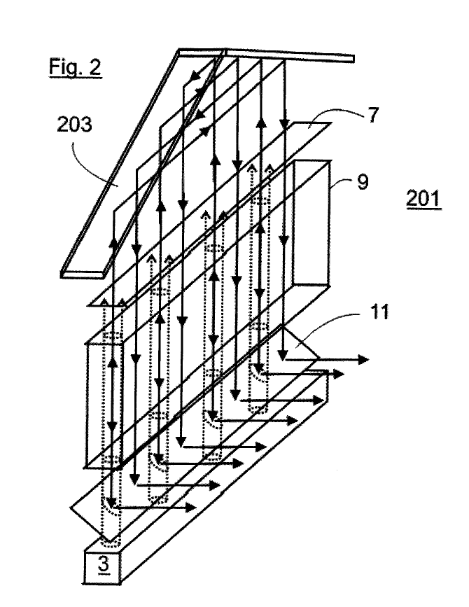

In order to decrease the size of the resulting beam according to a first embodiment of the present invention, as shown in FIG. 2, the generated green light, after being transmitted through the mirror 7 is redirected back into the PPLN-cuboid, shifted in such a way that it propagates in the spacings between the columns in direction to the mirror 11. In order to redirect the generated green light as described, the laser module 201 shown in FIG. 1 comprises a reflector 203 with two glass plates with reflecting coatings. The glass plates are arranged in such a way that they form a roof-like geometry. The glass plates are arranged perpendicular to each other. The reflector 203 is arranged to the laser module 203 in such a way, that the mirror 7 is situated between the PPLN-cuboid 9 and in such a way the right angle of reflector 203 and spans the mirror 7. The top line of the “roof” is perpendicular to the length of the laser diode array 3 and perpendicular to the direction of propagation of the green light. The top of the roof is displaced from the center of a laser cell by ¼ of the spacing of the lasercells. In this example this means it is displaced by 80 μm. By this displacement, one of the green beamlets transmitting thought the mirror 7 is displaced by 160 μm after being reflected from the two glass plates of the roof. Another beamlet is displaced by 480 μm, a third beamlet is displaced by 800 μm and the last beamlet is displaced by 1120 μm. All beamlets reflected in such a way therefore reenter into the PPLN-cuboid in spacings between the resonators of the VECSELs and, as not infrared light is present, don't interact with the PPLN. This is schematically shown in FIG. 2. As shown there as well, all 8 generated green beamlets are finally exiting the PPLN and propagating in direction to the mirror 11 where they are reflected out of the laser module.

There are as well other possibilities to realize a reflector for redirecting the beamlets in the way required.

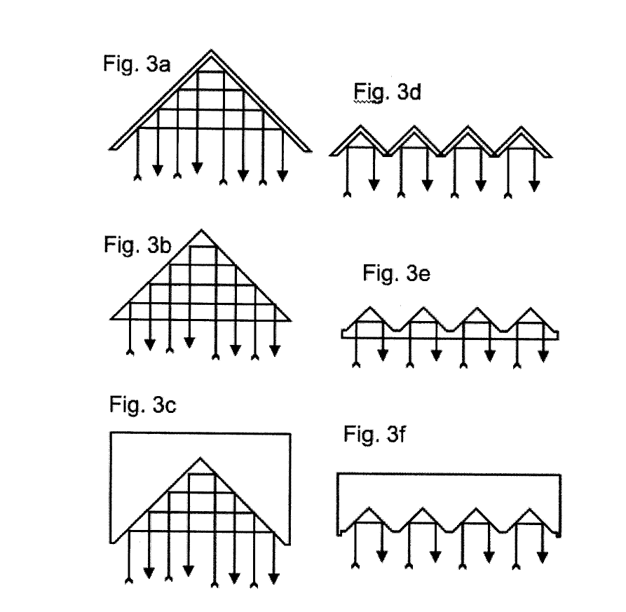

FIG. 3a-f shows a number of possible embodiments of such reflectors. FIG. 3a shows a cross section of reflector 203 as described in FIG. 2.

FIG. 3b shows the cross section of a transparent rectangular glass prism. The advantage to using such a glass prism as reflector is that total internal reflection can be used in order to redirect the generated beamlets. This is the case if glass is used which has a critical angle of total internal reflection well below 45°. This is for example for the well known and broadly used BK7 glass the case.

FIG. 3c shows a cross section of a block with a V-shaped groove, the V describing an angle of 90°. The side walls of the groove comprise a reflective coating. Such a block as shown has the advantage that it can be easily mounted as it may comprise means for mounting. Assembly of this block to the laser module is therefore no problem and cost efficient.

FIG. 3d shows the cross section of an embodiment of the reflector which resembles to the roof shaped reflector 203 of FIG. 2. However every single beamlet of generated green light has his own roof shaped reflector, arranged in an array. The beamlets are shifted by half a spacing of the lasercells only. Note that the overall height of this reflector is significantly decreased.

FIG. 3e shows an array of prisms in analogy to FIG. 3e. However these prisms are connected by a common substrate. This embodiment of the reflector may be produced by injection moulding of transparent plastic material such a polycarbonate or zeonex for example. The respective index of refraction is high enough for these materials in order to render total internal reflection well below 45°.

FIG. 3f shows another embodiment of the present invention, comprising multiple V-shaped groove reflectors in an array. The V-shaped rectangular grooves are coated with a reflecting coating such as for example a silver mirror coating or a dielectric mirror. The advantage of this embodiment of the reflectors is that the material does not need to be transparent.

It is clear that other embodiments of reflectors may be used. For example an array of reflectors may be used which its elements reflect two or three or any other number of beamlets of generated green light.

For clarity reasons the number of lasercells within the example was limited to 4. However it is possible and even typical to use laser diode arrays comprising by far more than these four lasercells. It is clear that the inventive principle may be directly applied to such an increased number. In particular it is clear that the principle of this invention may be even directly applied to laser diode arrays comprising more than one row, e.g. to a matrix of lasercells. In such a case it is preferred to shift the generated beamlets in the diagonal, which means as well between the rows of the matrix.

In the example only generated green light was discussed. However it is clear that the principle of this invention may be applied to any kind of frequency doubling of electromagnetic beams with the help of arrayed light sources.

What is claimed is:

1. Laser module with a linear laser diode array comprising multiple, mutually separated laser cells, and with a nonlinear optical material serving to double the frequency of the radiation emitted by the laser cells, in which the linear laser diode array and the nonlinear optical material are so positioned relative to each other that the resulting frequency-doubled radiation propagates, within the nonlinear optical material and essentially within mutually separated columns associable with the laser cells, both in the direction of the radiation emitted by the laser cells and in the opposite direction, said laser module comprising optical elements which divert the bidirectionally propagating frequency-doubled radiation in a manner whereby, upon diversion between the columns in the respective other direction, the radiation propagates in the nonlinear optical material, so that frequency-doubled light ultimately exits the nonlinear optical material in only one direction.

2. Laser module as in claim 1, characterized in that the optical elements include a rectangular prism which is so positioned relative to the nonlinear optical material that its hypotenuse surface constitutes the entry surface for the frequency-doubled radiation emanating from the nonlinear optical material in one direction and that the frequency-doubled radiation is totally reflected by both perpendicular cathetal surfaces of the prism and re-exits from the prism through the hypotenuse surface.

3. Laser module as in claim 2, characterized in that a prism of that type is assigned to each laser cell, so that these prisms form a prism array.

4. Method for generating frequency-doubled light, involving the following steps:
generation of laser light by means of a linear laser diode array;
insertion of a nonlinear optical material in the optical path of the laser light thus generated, in a manner whereby the laser light propagates in columns within the nonlinear material, producing frequency-doubled light that propagates in the columns both in the direction of the laser light and in the opposite direction; can
diversion of the frequency-doubled light propagating in one of the two directions in a manner whereby, upon such diversion between the columns, the light propagates in the other of the two directions and frequency-doubled light exits the nonlinear optical material essentially in only one direction.
